(19) United States
(12) Patent Application Publication
(10) Pub. No.: US 2007/0147008 A1
(43) Pub. Date: Jun. 28, 2007

(54) Use of porous materials to cool the surfaces of a computing device

(75) Inventor: Rajiv K. Mongia, Fremont, CA (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/321,034

(22) Filed: Dec. 28, 2005

(51) Int. Cl. H05K 7/20

(52) U.S. Cl. 361/719

(57) ABSTRACT

Embodiments disclosed herein include devices to cool the walls of a computer system. In one embodiment, a portion of a wall is comprised of a porous material to allow air to flow into the device. In another embodiment, a portion of porous material is mounted to the inside of a wall adjacent to a vent.

### BACKGROUND

Embodiments of the present invention relate to the field of heat management of computing devices and more specifically to cooling the outer surfaces of mobile computing devices.

Modern electronic circuits often generate a substantial amount of heat, due to their high density and small size. As platform power continues to increase while form factors continue to decrease, it will become increasingly difficult to cool platforms of the future. A particular challenge will be cooling of the outer surface of notebook computers or other mobile or handheld devices.

One example of a mobile computing device having a hot spot on the outer surface is illustrated in FIG. 1. The mobile computing device of FIG. 1 includes a heat generating component (104) mounted on a circuit board (102) within an enclosure (108). A hot spot (112) may exist on the enclosure adjacent to the component due to the heat that is generated by the component.

### BRIEF DESCRIPTION OF THE DRAWINGS

A better understanding of embodiments of the present invention can be obtained from the following detailed description in conjunction with the following drawings, in which:

FIG. 1 is an illustration of a cross-sectional view of a mobile computing device.

FIG. 2 is an illustration of a cross-sectional view of a mobile computing device enclosure including a porous material according to some embodiments.

FIG. 3 is an illustration of an enlarged cross-sectional view of a mobile computing device enclosure including a porous material according to some embodiments.

FIG. 4 is an illustration of a cross-sectional view of a vent configuration using a porous material according to some embodiments.

FIGS. 5A and 5B are illustrations of an overhead view of a mobile computing device enclosure utilizing a porous material according to some embodiments.

### DETAILED DESCRIPTION

In the following description, for purposes of explanation, numerous details are set forth in order to provide a thorough understanding of embodiments of the present invention. However, it will be apparent to one skilled in the art that these specific details are not required in order to practice the present invention as hereinafter claimed.

Embodiments of the present invention concern methods and devices for decreasing the temperature of portions of one or more walls of a mobile computing device. As used herein, a wall is defined as one side of an enclosure. A wall has an inner surface which faces the inside of the enclosure and an outer or exterior surface which faces the outside of the enclosure. A wall may be oriented in any direction, and is not limited to a horizontal or vertical orientation. Thus, a cube shaped enclosure may have six walls, which may be oriented in any direction. The term “skin” may also be used to refer to a wall of an enclosure.

Although the following discussion centers on mobile computing devices, it will be understood by those skilled in the art that the present invention as hereinafter claimed may be practiced in support of any type of heat generating electronic system, such as a server or a desktop computer.

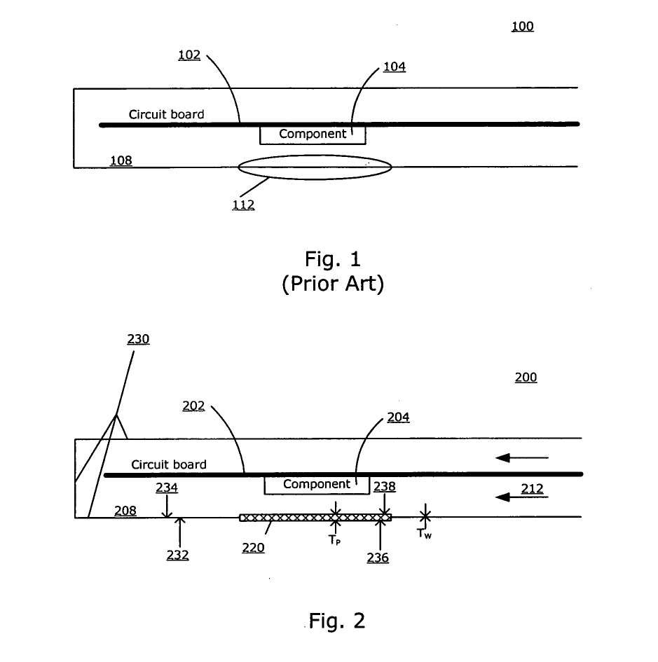

FIG. 2 illustrates a cross-sectional view of a mobile computing device (200) according to some embodiments. The mobile computing device includes a circuit board (202). One or more components (204) capable of generating heat are mounted to the circuit board. The component may be a microprocessor, a chipset device, a memory device, a voltage regulator, or other electronic component that is capable of generating heat when power is applied to the component.

The circuit board (202) and component (204) are contained within an enclosure or housing (208). The enclosure may include one or more walls (230), each wall having an exterior surface (232), an interior surface (234), and a thickness, T_{w}. At least one wall of the enclosure (208) may be substantially parallel to the circuit board (202). Air (212) may flow through the enclosure.

A portion of one or more walls of the enclosure may be comprised of a porous material (220) having an exterior surface (236), an interior surface (238) and a thickness, Tₚ. The porous material may be positioned on a wall that is substantially parallel to the circuit board, and may be adjacent to one or more heat generating components (204). In some embodiments, the porous material may be substantially centered on a wall of the enclosure with respect to one or more heat generating components. In some embodiments, the porous material may be located on any portion of the enclosure where cooling of the outer surface of the enclosure is desired. Use of the porous material for all or a portion of one or more walls of the enclosure allows the exterior surface of the porous portion of the wall to be cooled in the region where the porous material is used.

Some embodiments may include multiple heat generating components (204). Furthermore, some embodiments may include multiple circuit boards (202).

The porous material may have the same thickness as the walls of the enclosure. In other embodiments, the thickness of the porous material may be greater than or less than the thickness of the walls of the enclosure. The exterior surface of the porous material (236) may be in the same plane as the exterior surface of the wall (232). The porous material may be attached to the wall of the enclosure using an adhesive material, or may be attached using other mechanical means, such as screws or a snap or latching mechanism.

In some embodiments, the porous material may have pores ranging in size from 1 micron to 1 mm. The pores of the porous material allow air to be drawn through the pores of the material from one side to the other. In some embodiments, the porous material may visually appear to be a solid material.

In some embodiments, the porous material may be a porous metal material, such as a sintered metal plate. In an embodiment where the porous material is a sintered metal plate or other porous metal material, the porous metal material may also provide EMI protection for the mobile computing device.

In other embodiments, the porous material may be a porous plastic material, a porous ceramic material, a porous carbon fiber material, a porous fabric material, or another porous material.

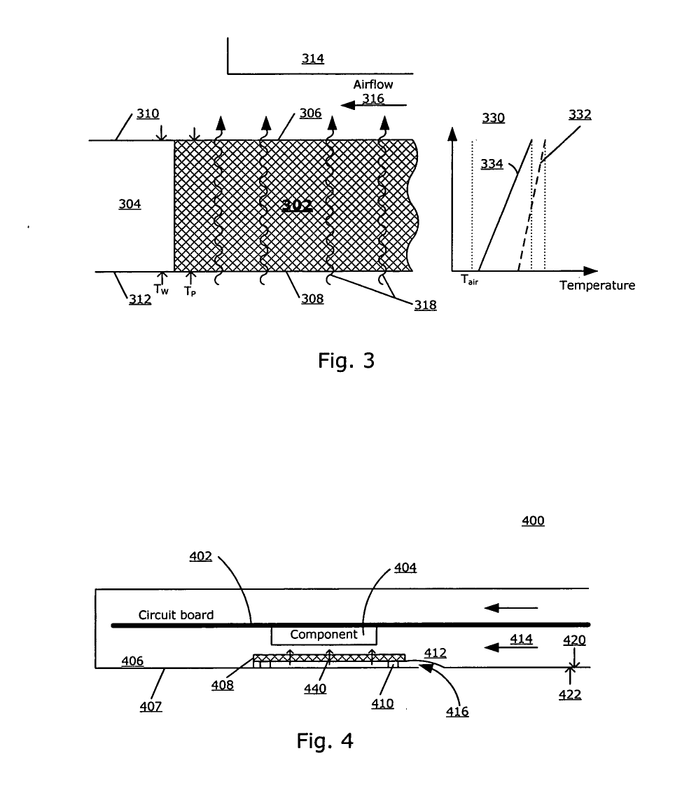

FIG. 3 illustrates a magnified cross-sectional view of a mobile computing device according to some embodiments. As described above, with respect to FIG. 2, a portion of a wall (304) of a mobile computing device enclosure is comprised of a porous material (302). The porous material may be located adjacent to, or in close proximity to a heat-generating device (314).

The wall (304) has an exterior surface (312), an interior surface (310) and a thickness, Tw. The porous portion of the wall (302) also has an exterior surface (308), an interior surface (306) and a thickness, Tₚ. In the example of FIG. 3, the thickness of the wall, Tw, is equal to the thickness of the porous material, Tₚ, however the thickness of each may differ.

Airflow through the mobile computing device enclosure (316) may cause the air pressure inside of the enclosure to be less than the air pressure outside of the enclosure. The pressure differential between the inside and outside of the enclosure will cause air (318) to be drawn through the porous material (302) into the enclosure.

As air passes through the porous material, heat transfer will cause the air to cool the porous material. Thus, the exterior surface of the porous material will remain close to the ambient air temperature. As the air is drawn through porous material, the air will cool the outer surface of the material with a very high heat transfer coefficient due to flow through the small passages in the porous material.

A graph (330) illustrates example temperature gradients through different wall materials. The solid line (334) illustrates the temperature gradient of the portion of wall comprised of porous material (302), while the dashed line (332) illustrates a temperature gradient for the same portion of the wall, but comprised of a non-porous material. As indicated by the solid line (334), at the exterior surface (308) of the porous material, the temperature of the porous material is very close to the temperature of the ambient air. The temperature increases as the air passes through the porous material, and the temperature at the interior surface (306) of the porous material is greater than the temperature at the exterior surface (308) of the porous material. In some embodiments, there may not be a significant temperature gradient within the porous material; however, the temperature of the porous material may still be less than that of a non-porous surface. The temperature gradient of a porous wall material (334) may be improved as compared to the temperature gradient of a non-porous wall material (332). A non-porous material has increased temperatures at both the exterior surface and the interior surface as compared to a porous material.

FIG. 4 illustrates a cross-sectional view of a mobile computing device (400) according to another embodiment. The mobile computing device includes a circuit board (402) having a component (404) capable of generating heat mounted to the circuit board. The component may be a microprocessor, a chipset device, a memory device, or other electronic component that is capable of generating heat.

The circuit board (402) and component (404) are contained within an enclosure or housing (406). The enclosure may include one or more walls (407) having an inner surface (420) and an outer surface (422). At least one wall of the enclosure may be substantially parallel to the circuit board. One or more vents (412) may be formed in a wall of the enclosure.

A portion of porous material (408) may be mounted on the inner surface of an enclosure wall (407). The porous material may be attached directly to the wall, or may be separated from the wall using spacers (410), as illustrated. The porous material may be mounted on a wall that is substantially parallel to the circuit board, and may be adjacent to one or more heat generating components (404). In some embodiments, the porous material may be substantially centered on a wall of the enclosure with respect to one or more heat generating components. In some embodiments, the porous material may be located on any portion of the enclosure where cooling of the outer surface of the enclosure is desired. Mounting of the porous material on a wall within the enclosure may allow an exterior surface of the wall to be cooled in the region where the porous material is used. In some embodiments, the porous material (408) may be mounted on the interior surface of the wall in fluidic communication with the vent (412).

Airflow (414) within the interior of the mobile device lowers the pressure within the device, thus drawing air (416) from outside of the device in through the vent (412). The air may then be drawn up (440) through the porous material (408). This may cool the portion of the wall that is beneath the porous material, thus reducing hot spots on the outer surface of the enclosure.

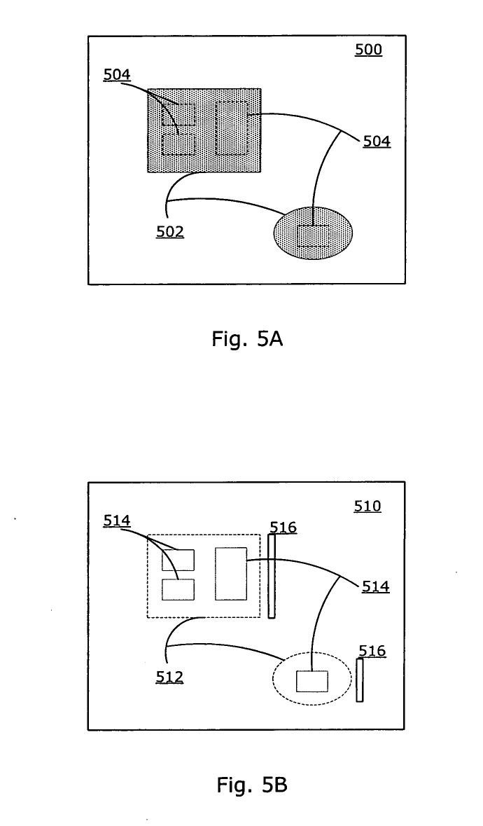

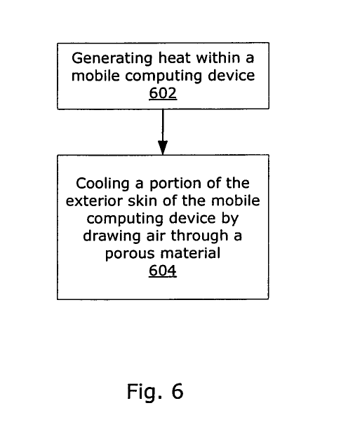

FIGS. 5A and 5B illustrate overhead views of an exterior surface of a device wall according to some embodiments. FIG. 5A illustrates the exterior surface of a wall (500) where one or more portions of the wall (502) are comprised of a porous material. The porous portions of the wall may be positioned over heat generating components (504), or in other regions where cooling of the outer surface is desired. Each porous portion (502) may be positioned over one or more components (504). The porous portion may be substantially centered with respect to the one or more components. The porous portion may be rectangular in shape, or may be another polygonal, elliptical, or other shape, including an abstract shape.

As described above, with respect to FIGS. 2 and 3, the use of porous material for portions of the outer surface of a wall effectively cools the exterior surface of the device in the porous region.

For a porous material such as sintered metal plate, which has a relatively high flow resistance, a large percentage of a wall may be constructed of the porous material while still providing sufficient resistance to obtain uniform airflow into the device. Thus, it may be possible for an entire wall (500) to be constructed of a porous material.

FIG. 5B illustrates the exterior surface of a wall (510) where portions of a porous material are mounted inside of an enclosure wall (510), as described in conjunction with FIG. 4, above. The porous material is mounted over heat generating components (514). The porous material (512) may be positioned over one or more components (514) and may be substantially centered with respect to the one or more components. Vents (516) may be located near the porous material in order to draw air into the device to cool the outer surface, as described above, with respect to FIG. 4. In other embodiments, the vents (516) may be located some distance from the porous material (512).

FIG. 6 is a flow diagram illustrating a method of cooling a mobile computing device according to some embodiments. In block 502, heat is generated within a mobile computing device, such as a notebook computer. The heat may be generated by a microprocessor or other electronic component with the computing device, as described above in conjunction with FIG. 2. In block 504, a portion of the outer surface may be cooled by drawing air into the mobile computing device through a porous material which may comprise part of the mobile computing device enclosure. In some embodiments, the cooled portion of the enclosure may be the portion of the enclosure comprised of the porous material.

Thus, a method, apparatus, and system for cooling the surface of a mobile computing device are disclosed. In the above description, numerous specific details are set forth. However, it is understood that embodiments may be practiced without these specific details. In other instances, well-known circuits, structures, and techniques have not been shown in detail in order not to obscure the understanding of this description. Embodiments have been described with reference to specific exemplary embodiments thereof. It will, however, be evident to persons having the benefit of this disclosure that various modifications and changes may be made to these embodiments without departing from the broader spirit and scope of the embodiments described herein. The specification and drawings are, accordingly, to be regarded in an illustrative rather than a restrictive sense.

I claim:

1. A computing device, comprising:
a circuit board;
a component capable of generating heat mounted on the circuit board; and
an enclosure to surround the circuit board, the enclosure having a wall, wherein a portion of the wall is comprised of a porous material to draw air into the enclosure.

2. The computing device of claim 1, wherein the wall is substantially parallel to the circuit board.

3. The computing device of claim 1, wherein the component is a microprocessor.

4. The computing device of claim 2, wherein the portion of the wall comprised of the porous material is positioned adjacent to the component.

5. The computing device of claim 4, wherein the portion of the wall comprised of the porous material is substantially centered with respect to the component.

6. The computing device of claim 1, wherein the porous material has pores with a maximum pore size of 1 mm.

7. The computing device of claim 6, wherein the porous material is metal.

8. The computing device of claim 7, wherein the porous material is a sintered metal plate.

9. The computing device of claim 7, wherein the porous material visually appears to be a solid material.

10. The computing device of claim 6, wherein the porous material is a plastic material.

11. An apparatus, comprising:
a circuit board;
a component capable of generating heat mounted on the circuit board;
an enclosure to surround the circuit board, the enclosure having a wall that is substantially parallel to the circuit board, wherein the wall has an inner surface and an outer surface;
a vent formed within the wall to draw air into the enclosure; and
a portion of porous material mounted on the inner surface of the wall in fluidic communication with the vent, the air to flow through the portion of the porous material.

12. The apparatus of claim 11, wherein the portion of porous material is separated from the inner surface of the wall by spacers.

13. The apparatus of claim 11, wherein the portion of porous material is mounted adjacent to the component.

14. The apparatus of claim 11, wherein the portion of porous material is substantially centered with respect to the component.

15. The apparatus of claim 11, wherein the portion of porous material has pores with a maximum pore size of 1 mm.

16. The apparatus of claim 15, wherein the portion of porous material is a sintered metal plate.

17. The apparatus of claim 15, wherein the portion of porous material is a plastic material.

18. A method comprising:
generating heat within a mobile computing device having an outer surface; and
cooling the outer surface of the mobile computing device by drawing air from outside of the mobile computing device through a porous material.

19. The method of claim 18, wherein at least a portion of the outer surface of the mobile computing device is comprised of the porous material.

20. The method of claim 18, wherein the porous material is a sintered metal plate.
